(19) United States
(12) Patent Application Publication
(10) Pub. No.: US 2007/0121300 A1
(43) Pub. Date: May 31, 2007

(54) BACK PLATE ASSEMBLY FOR MOUNTING A HEAT SINK ASSEMBLY TO A MOTHERBOARD

(76) Inventors: Wan-Lin Xia, Shenzhen (CN); Tao Li, Shenzhen (CN); Jun Zhang, Shenzhen (CN); Ji-Yun Qin, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/164,535

(22) Filed: Nov. 29, 2005

(51) Int. Cl. H05K 7/20

(52) U.S. Cl. 361/719

(57) ABSTRACT

A back plate assembly for a motherboard includes a back plate, four posts and four plastic rings. The back plate abuts against an underside of the motherboard. The posts extend from the back plate and pass through the motherboard. The rings engage with the posts respectively and elastically abut against an upside of the motherboard.

### FIELD OF THE INVENTION

The present invention relates generally to a back plate assembly, and more particularly to a back plate assembly which is pre-assembled to a motherboard to facilitate mounting of a heat sink assembly to the motherboard.

### DESCRIPTION OF RELATED ART

Computer electronic devices such as central processing units (CPUs) frequently generate large amounts of heat, which can destabilize operation and cause damage to the electronic devices. A heat sink is placed in thermal contact with an electronic device for transferring heat from the electronic device to atmosphere through conduction and convection. Modern heat sinks are being made larger and larger. Therefore, a back plate is often attached on an underside of a motherboard below an electronic device mounted on the motherboard. The back plate reinforces the motherboard and facilitates the mounting of the heat sink to the motherboard so that the heat sink can have an intimate contact with the electronic device.

FIGS. 6-7 show a conventional back plate 1 for attachment below a motherboard 14. The motherboard 14 has a heat sink assembly 10 secured thereon. The back plate 1 comprises a base 2, and four U-shaped protrusions 3 extending from four corners of the base 2, respectively. Each protrusion 3 defines a cutout 4 in an outmost extremity thereof. The motherboard 14 defines four through holes (not labeled). The heat sink assembly 10 comprises four hollow poles 12 depending from an underside thereof.

In assembly, the heat sink assembly 10 is attached on the motherboard 14 with the poles 12 extending through the through holes of the motherboard 14. The back plate 1 is then attached to an underside of the motherboard 14, with the cutouts 4 of the back plate 1 in communication with the corresponding through holes of the motherboard 14. The poles 12 extend through the corresponding cutouts 4. Screws 16 are then extended through the corresponding cutouts 4 to engage in the hollow poles 12 thereby screwing the back plate 1 to the poles 12.

The back plate 1, the screws 16, the heat sink assembly 10 and the motherboard 14 are separated from each other before they are assembled together. None of them can be preassembled beforehand. This is disadvantageous in view of inventory management and transportation. Furthermore, the process of assembling the back plate 1, the screws 16, the heat sink assembly 10 and the motherboard 14 is time-consuming and inconvenient.

### SUMMARY OF INVENTION

A back plate assembly in accordance with a preferred embodiment of the present invention comprises a back plate, four posts and four plastic rings. The back plate abuts against an underside of a motherboard. The posts extend from the back plate and pass through the motherboard. The rings engage with the posts respectively and elastically abut against an upside of the motherboard. The posts form threaded portions at upper ends thereof. A plurality of fixing components are brought to extend through a heat sink assembly to threadedly engage with the threaded portions thereby securing the heat sink assembly to the motherboard so that the heat sink assembly can effectively take heat away from a heat generating electronic component mounted on the mother board.

Other advantages and novel features will become more apparent from the following detailed description of preferred embodiments when taken in conjunction with the accompanying drawings, in which:

### BRIEF DESCRIPTION OF DRAWINGS

FIG. 1 is an isometric view of a back plate assembly in accordance with a preferred embodiment of the present invention;

FIG. 2 is an exploded view of the back plate assembly of FIG. 1;

FIG. 3 is an assembled view of the back plate assembly of FIG. 1 and a motherboard;

FIG. 4 is an enlarged cross-sectional view taken along line IV-IV of FIG. 3;

FIG. 5 is an assembled view of the back plate assembly of FIG. 1, together the motherboard, a heat sink assembly, and fixing components to secure the heat sink assembly to the motherboard;

FIG. 6 is an isometric view of a conventional back plate; and

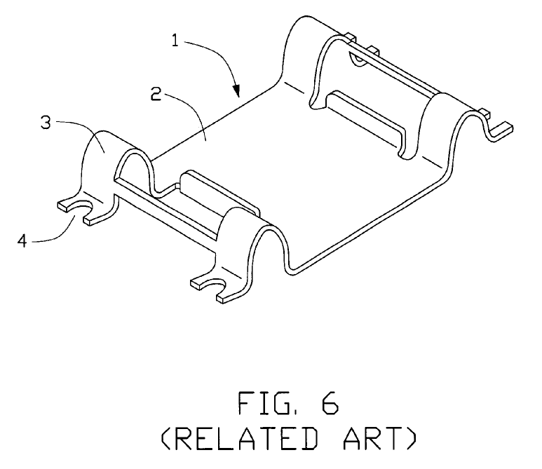

FIG. 7 is a schematic cross-sectional view of the back plate of FIG. 6 securing a heat sink assembly to a motherboard.

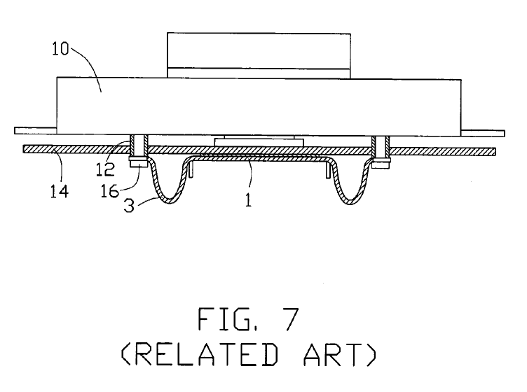

### DETAILED DESCRIPTION

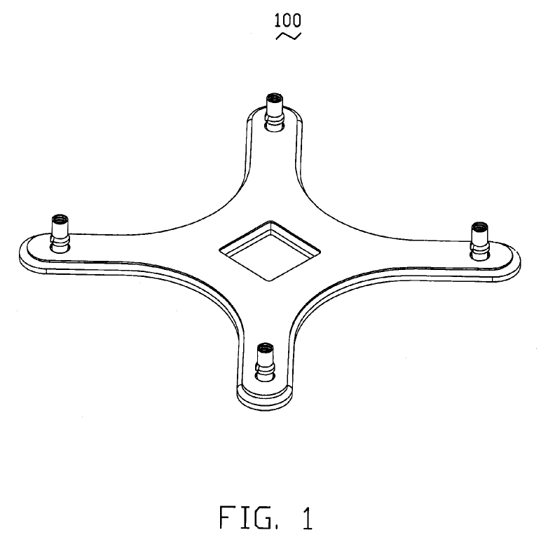

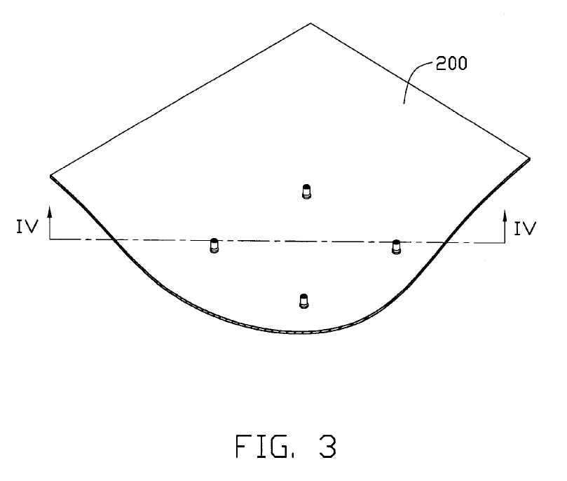

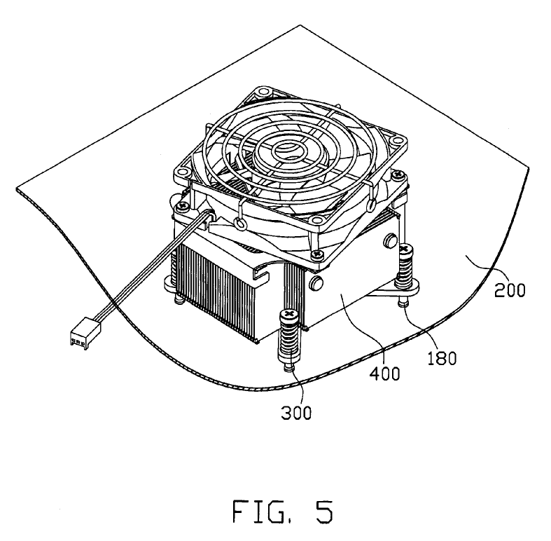

Referring to FIGS. 1-5, a back plate assembly 100 in accordance with a preferred embodiment of the invention comprises a back plate 110, four posts 160 and four elastic rings 180. The back plate 110 abuts against an underside of a printed circuit board which may be a motherboard 200 as shown in FIGS. 3-5. The motherboard 200 defines four apertures (not labeled). The posts 160 secured to the back plate 110 can pass through the apertures of the motherboard 200 and engage with four fixing components 300, such as screws to secure a heat sink assembly 400 to the motherboard 200. The elastic rings 180 clasps the posts 160, respectively, and elastically abut against an upside of the motherboard 200.

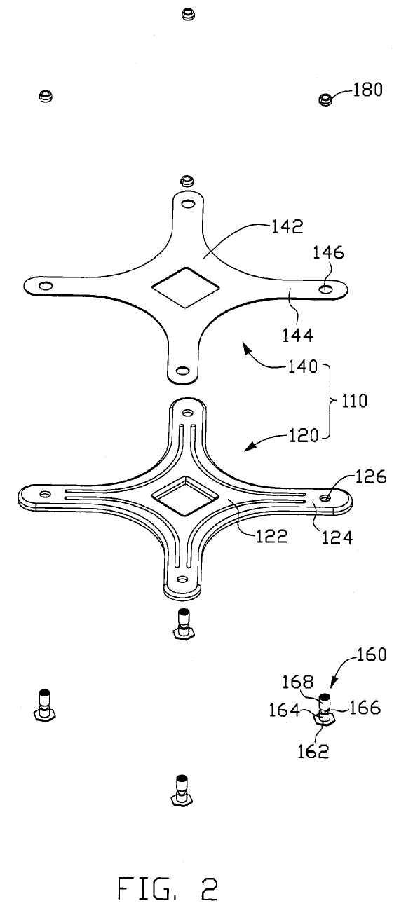

Referring to FIGS. 1-2, the back plate 110 comprises a cross-shaped rack 120 and a cross-shaped insulated slice 140. The rack 120 is made of metallic material in the preferred embodiment, and comprises a rectangular base 122 and four arms 124 extending outwardly from four diagonal corners of the base 122, respectively. Each arm 124 defines a through hole 126 at an extremity thereof. The insulated slice 140 has a configuration similar to the configuration of the rack 120. The insulated slice 140 is conformably laid on a top surface of the rack 120 and secured thereto by adhesive. The insulated slice 140 has a rectangular base 142 and four arms 144 extending outwardly from four diagonal corners of the base 142, respectively. Each arm 144 defines a hole 146 at an extremity thereof. The hole 146 is aligned with a corresponding hole 126 in the rack 120.

Each post 160 comprises a head portion 162, a pole portion 164, a neck portion 166 and a threaded portion 168 extending from the neck portion 166. The pole portion 164 extends from the head portion 162 and has a diameter less than a diameter of the head portion 162. The neck portion 166 extends from the pole portion 164 and has a diameter less than the diameter of the pole portion 164 and a diameter of the threaded portion 168. For the back plate assembly 10, a distance between the neck portion 166 and the insulated slice 140 of the back plate 110 is substantially equal to a thickness of the motherboard 200. The threaded portion 168 is substantially a hollow cylinder and forms a spiral thread on an inner wall thereof. Referring to FIGS. 2-4, the head portions 162 of the posts 160 abut against a bottom surface of the rack 120. The pole portions 164 engage in the through holes 126 of the rack 120 so that the posts 160 are secured to the back plate 110. The pole portions 164 further extend upwardly above the insulated slice 140 of the back plate 110.

Each elastic ring 180 is an open C-shaped ring. The rings 180 can be elastically expanded in a radial direction when an expanding force in the radial direction is applied to them, so that the elastic rings 180 are capable of engaging with the neck portions 166 of the posts 160, respectively. The elastic rings 180 have a slight degree of deformability. In the preferred embodiment, the elastic rings 180 are made of plastic material. An inner diameter of each elastic ring 180 is substantially smaller than the diameter of each neck portion 166 and an outer diameter of each elastic ring 180 is substantially larger than a diameter of each aperture of the motherboard 200 before the elastic rings 180 are brought to clasp the neck portions 166, so that the elastic rings 180 can securely engage with the neck portions 166 to be combined to the posts 160 and elastically abut against the upside of the motherboard 200.

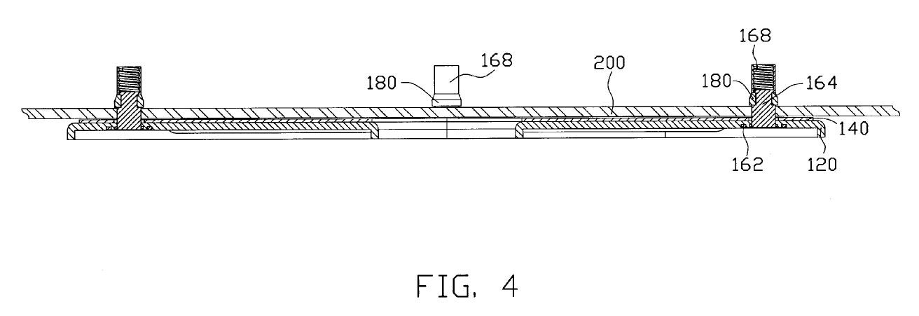

Particularly referring to FIGS. 3-4, in installation of the back plate assembly 100 to the motherboard 200, the neck portions 166 and the threaded portions 168 of the posts 160 are brought to pass through the apertures of the motherboard 200 until the threaded portions 168 and the neck portions 166 are located above the upside of the motherboard 200. The insulated slice 140 thus abuts against the underside of the motherboard 200. The elastic rings 180 are then engaged with the neck portions 166 and elastically abut against the upside of the motherboard 200 to thereby securely attach the posts 160 to the motherboard 200. Accordingly, the back plate assembly 100 is pre-assembled to the motherboard 200.

It is clearly shown that the elastic rings 180 can have the back plate assembly 100 to be pre-assembled to the motherboard 200. This is advantageous in view of inventory management and transportation of the back plate assembly 100 and the motherboard 200. Since the back plate assembly 100 can be pre-assembled to the motherboard 200, the heat sink assembly 400 can be secured to the motherboard 200 so long as the fixing components 300 are brought to extend through ears (not labeled) of a heat sink (not labeled) of the heat sink assembly 400 and threadedly engage in the threaded portions 168 of the posts 160. The present invention dramatically simplifies the assembly process of fixing the heat sink assembly 400 to the motherboard 200. Additionally, since the elastic rings 180 are elastic, they can absorb excessive force exerted on the back plate 110 and the motherboard 200 to protect the back plate 110 and the motherboard 200 from being damaged.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A back plate assembly for a motherboard, comprising:
a back plate abutting against an underside of the motherboard;
a plurality of posts extending from the back plate and passing through the motherboard; and
a plurality of elastic rings engaging around the plurality of posts respectively and elastically abutting against an upside of the motherboard.

2. The back plate assembly as claimed in claim 1, wherein the elastic rings are open C-shaped rings and have a slight degree of deformability.

3. The back plate assembly as claimed in claim 1, wherein the elastic rings are made of plastic material.

4. The back plate assembly as claimed in claim 1, wherein each of posts comprises a head portion, a pole portion extending from the head portion, a neck portion extending from the pole portion and a threaded portion extending from the neck portion.

5. The back plate assembly as claimed in claim 4, wherein the head portions of the posts abut against an underside of the back plate.

6. The back plate assembly as claimed in claim 4, wherein the threaded portion is a hollow cylinder and defines spiral threads on an inner wall thereof.

7. The back plate assembly as claimed in claim 4, wherein the pole portion had a diameter less than a diameter of the head portion and is engaged with the back plate.

8. The back plate assembly as claimed in claim 4, wherein the neck portion has a diameter less than a diameter of the pole portion and less than a diameter of the threaded portion.

9. The back plate assembly as claimed in claim 8, wherein the elastic rings surround the neck portions of the posts.

10. The back plate assembly as claimed in claim 1, wherein the back plate comprises a cross-shaped rack and an insulated slice laid on the rack and abutting against the underside of the motherboard.

11. The back plate assembly as claimed in claim 10, wherein the rack and the insulated slice each define through holes for the posts extending therethrough.

12. A combination comprising:
a plurality of posts, each of the posts comprising a head portion, a pole portion extending from the head portion, a neck portion extending from the pole portion;
a plurality of rings elastically engaging with the neck portions of the posts;
a motherboard defining a plurality of apertures therein; and
a back plate attached to an underside of the motherboard and defining a plurality of through holes therein corresponding to the apertures in the motherboard;
wherein the pole portions are received in the through holes of the back plate and the motherboard, the head portions and the rings elastically sandwich the motherboard and the back plate therebetween.

13. The combination as claimed in claim 12, wherein the head portions abut against an underside of the back plate, and wherein the rings elastically abut against an upside of the motherboard.

14. The combination as claimed in claim 12, wherein each of the posts further comprises a threaded portion extending from the neck portion and having a diameter thereof larger than a diameter of the neck portion.

15. The combination as claimed in claim 12, wherein the rings are open C-shaped rings and have a slight degree of deformability.

16. An electronic assembly comprising:
a circuit board having an underside, an upside opposite the underside and a plurality of through holes through the underside and upside;
a back plate assembly having:
a rack made of metal;
an insulated slice sandwiched between the rack and the underside of the circuit board;
a plurality of posts secured to the rack and extending upwardly through the through holes in the circuit board, each post having a neck portion and a threaded portion located above the upside of the circuit board, wherein the threaded portion is located above the neck portion;
a plurality of retaining members engaging with the neck portions of the posts, respectively, and abutting against the upside of the circuit board;
a heat sink assembly mounted on the upside of the circuit board; and
a plurality of fixing components extending through the heat sink assembly to threadedly engage with the threaded portions of the posts to thereby secure the heat sink assembly to the circuit board.

17. The electronic assembly as claimed in claim 16, wherein the retaining members are made of plastics and have a degree of elasticity and deformability, each of the retaining members having a ring-shaped configuration.

18. The electronic assembly as claimed in claim 16, wherein the retaining members are C-shaped rings which can be expanded radially.

19. The electronic assembly as claimed in claim 18, wherein each of the C-shaped rings has an outer diameter larger than that of the through hole of the circuit board and an inner diameter smaller than that of the neck portion before the C-shaped rings are brought to engage with the neck portions of the posts.

20. The electronic assembly as claimed in claim 16, wherein the rack is cross-shaped having a rectangular main body and four arms extending outwardly from four corners of the main body, respectively, the posts being attached to extremities of the arms respectively.
